(19) United States
(12) Patent Application Publication
(10) Pub. No.: US 2013/0118578 A1
(43) Pub. Date: May 16, 2013

(54) SUBSTRATE FOR ELECTRONIC DEVICE, AND PHOTOELECTRIC CONVERSION DEVICE INCLUDING THE SAME

(71) Applicant: Fujifilm Corporation, Tokyo (JP)

(72) Inventors: Atsushi MUKAI, Kanagawa-ken (JP); Naruhiko AONO, Kanagawa-ken (JP)

(73) Assignee: FUJIFILM CORPORATION, Tokyo (JP)

(21) Appl. No.: 13/737,783

(22) Filed: Jan. 9, 2013

Related U.S. Application Data
(63) Continuation of application No. PCT/JP2011/003991, filed on Jul. 12, 2011.

(30) Foreign Application Priority Data
Jul. 14, 2010 (JP) 159517/2010

(51) Int. Cl. H05K 1/05; H01L 31/042

(52) U.S. Cl. CPC H05K 1/053; H01L 31/0422
USPC 136/256; 174/255

(57) ABSTRACT

A substrate for an electronic device is formed by an insulating layer-provided metal substrate, which includes an anodized alumina film on the surface of a metal substrate and has a cut end face at at least one side thereof, and an electrode layer, which is provided only at an inner area that is away from the cut end face by a distance of 200 μm or more.

### BACKGROUND OF THE INVENTION

1. Field of the Invention

The present invention relates to a substrate for an electronic device, such as a solar battery, TFT, etc., and a photoelectric conversion device including the substrate.

2. Description of the Related Art

The main stream of conventional solar batteries has been Si solar batteries, which use bulk single-crystal Si or polycrystal Si, or thin-film amorphous Si. On the other hand, compound semiconductor solar batteries, which do not depend on Si, are now being researched and developed. As the compound semiconductor solar batteries, those of a bulk type, such as GaAs solar batteries, and those of a thin-film type, such as CIS (Cu—In—Se) or CIGS (Cu—In—Ga—Se) solar batteries, which contain a group Ib element, a group IIIb element and a group VIb element, are known. The CIS or CIGS solar batteries are reported to have high light absorption rate and high photoelectric conversion efficiency, and are gathering attention as next-generation solar batteries that allow reduction of the module production costs.

As a substrate for forming a solar battery module, it is proposed to use, for example, a substrate including anodized aluminum (alumina) formed on aluminum (see, for example, Japanese Unexamined Patent Publication Nos. 2009-132996 and 2009-267336). The alumina serves as an insulating layer and allows integration, thereby allowing reduction of the module production costs. Further, it allows providing a flexible substrate, which can be used with a roll-to-roll process, and a further cost reduction is expected.

### SUMMARY OF THE INVENTION

The present applicant has proposed, in Japanese Patent Application No. 2010-053202, etc., using a substrate that includes an anodized film on the surface of aluminum of a cladding material which is formed by an aluminum material and a metal base material having a coefficient of linear thermal expansion close to that of the CIGS layer to prevent warping and cracking caused due to a difference of thermal expansion during a heating process for forming various films on the substrate, which is the case with an aluminum substrate having one surface thereof anodized.

The present inventors have found, through an intense study of a process of forming an integrated photoelectric conversion device in a roll-to-roll process using a flexible long substrate including the anodized aluminum film on the above-described aluminum cladding material, and photoelectric conversion characteristics, etc., thereof, that, when a substrate having elements formed thereon is cut into individual modules after a photoelectric conversion element formation process including a patterning process for integration, a failure, such as a short circuit between a back electrode formed on the anodized aluminum film and a metal base material under the anodized aluminum film or lowering of the breakdown voltage of the element, occurs.

When a short circuit is formed between the back electrode and the metal base material, the module does not work, and the lowering of the breakdown voltage results in poor function of the photoelectric conversion element and is undesirable. It is believed that the same problem occurs when other types of electronic devices which are preferably formed on an insulating substrate are provided in the form of a flexible device.

In view of the above-described circumstances, the present invention is directed to providing a substrate for an electronic device, which is less likely to cause breakdown during a process to form an electronic device on the substrate and result in the electronic device that cannot be driven. The present invention is also directed to providing a photoelectric conversion device including the above-described substrate.

For a process of cutting an insulating layer-provided metal substrate that includes an anodized film formed on aluminum of a cladding material, which is formed by aluminum and another metal, a press cutter or a dicing saw is used. The present inventors have found that the anodized film is damaged during this cutting process, and cracks form under the electrode layer that is formed on the insulating layer. The present inventors have found that, when the cracks form, fragments of the back electrode may connect between the back electrode and the metal layer of the substrate and cause a short circuit phenomenon. Further, the present inventors have found that, at a cracked portion, an air layer forms between the back electrode and the metal layer of the substrate, and the presence of the air layer lowers the partial discharge voltage. Still further, the present inventors have found that the cracks due to the cutting form within a limited range from the cut position. The present invention has been achieved based on these findings.

A first aspect of a substrate for an electronic device of the invention includes: an insulating layer-provided metal substrate including an anodized alumina film on the surface of a metal substrate, the insulating layer-provided metal substrate including a cut end face at at least one side thereof; and an electrode layer provided on the insulating layer-provided metal substrate only at an inner area that is away from the cut end face by a distance of 200 μm or more.

It is more desirable that the electrode layer is provided only at an inner area that is away from the cut end face by a distance of 300 μm or more.

It is desirable that the metal substrate is formed by an Al material and a metal base material that has a smaller coefficient of linear thermal expansion, higher rigidity and higher heat resistance than Al, which are integrated together.

As the metal base material, a steel material is particularly preferable.

A second aspect of the substrate for an electronic device of the invention includes: an insulating layer-provided metal substrate including an anodized alumina film on the surface of a metal substrate, the insulating layer-provided metal substrate including a cut end face at at least one side thereof; and an electrode layer uniformly formed on the anodized alumina film on the insulating layer-provided metal substrate, wherein the electrode layer is electrically separated into an end face area and an inner area at a predetermined position that is away from the cut end face of the insulating layer-provided metal substrate by a distance of 200 μm or more.

It is desirable that the predetermined position is away from the cut end face by a distance of 300 μm or more.

It is desirable that the metal substrate is formed by an Al material and a metal base material that has a smaller coefficient of linear thermal expansion, higher rigidity and higher heat resistance than Al, which are integrated together.

As the metal base material, a steel material is particularly preferable.

A first aspect of a photoelectric conversion device of the invention includes: the first aspect of the substrate for an electronic device of the invention; and a photoelectric conversion layer and a transparent electrode layer formed in this order on the electrode layer of the substrate for an electronic device, wherein the electrode layer, the photoelectric conversion layer and the transparent electrode layer form a photoelectric conversion circuit.

A second aspect of the photoelectric conversion device of the invention includes: the second aspect of the substrate for an electronic device of the invention; and a photoelectric conversion layer and a transparent electrode layer formed in this order on the electrode layer of the substrate for an electronic device, wherein the photoelectric conversion layer and the transparent electrode layer, together with the electrode layer, are separated into an end face area and an inner area at the predetermined position, and the electrode layer, the photoelectric conversion layer and the transparent electrode layer formed at the inner area form a photoelectric conversion circuit.

It is desirable as the photoelectric conversion device that the photoelectric conversion layer is formed by a compound semiconductor, and the photoelectric conversion device further includes a buffer layer between the photoelectric conversion layer and the transparent electrode layer.

In the first aspect of the substrate for an electronic device of the invention, the electrode layer is provided only at an inner area that is away from the cut end face by a distance of 200 μm or more on the insulating layer-provided metal substrate, which includes the anodized film as the insulating layer on the surface thereof. Therefore, the electrode layer is scarcely affected by cracks that form in the vicinity of the cut end face during cutting, and has excellent voltage endurance. Also, in a case where an electronic device is formed on the substrate, it is less likely to result in an electronic device that cannot be driven, due to good insulation between the metal substrate and the electrode layer on the anodized film, and use of the substrate of the invention improves production efficiency of the electronic device.

In the second aspect of the substrate for an electronic device of the invention, the electrode layer formed on the insulating layer-provided metal substrate, which includes the anodized film as the insulating layer on the surface thereof, is electrically separated into the end face area and the inner area at a predetermined position that is away from the cut end face by a distance of 200 μm or more. Therefore, the electrode layer at the inner area of the substrate is scarcely affected by cracks that form in the vicinity of the cut end face during cutting, and has excellent voltage endurance. Also, in a case where an electronic device is formed on the electrode layer at the inner area of the substrate, it is less likely to result in an electronic device that cannot be driven, due to good insulation between the metal substrate and the electrode layer at the inner area of the substrate, and use of the substrate of the invention improves production efficiency of the electronic device.

The first and second aspects of the photoelectric conversion device of the invention include the above-described substrate for an electronic device of the invention, and therefore have excellent voltage endurance characteristics with respect to breakdown and high reliability.

### BRIEF DESCRIPTION OF THE DRAWINGS

FIG. 1 is a perspective view illustrating the schematic structure of a substrate for an electronic device of a first embodiment,

FIG. 2 is a sectional view illustrating end areas and an electrode layer formation area of the substrate 1 for an electronic device,

FIG. 3 is a perspective view illustrating a modification of the substrate for an electronic device of the first embodiment,

FIG. 4 is a perspective view illustrating the schematic structure of a substrate for an electronic device of a second embodiment,

FIG. 5 is a perspective view illustrating the schematic structure of a substrate for an electronic device of a third embodiment,

FIG. 6 is a sectional view illustrating end areas and an electrode layer formation area of the substrate 3 for an electronic device,

FIG. 7 is a sectional view illustrating a part of a photoelectric conversion device of a first embodiment,

FIG. 8 is a perspective view illustrating a substrate for an electronic device of the invention included in the photoelectric conversion device shown in FIG. 7,

FIG. 9 is a sectional view illustrating a part of a photoelectric conversion device of a second embodiment,

FIG. 10 is a microscopic image of the vicinity of a cut end face,

FIG. 11 is a graph showing a probability distribution of crack penetration length, and

FIG. 12 is a schematic diagram illustrating a resistance measurement method used in a verification experiment.

### DESCRIPTION OF THE PREFERRED EMBODIMENTS

Hereinafter, embodiments of a substrate for an electronic device of the present invention, and embodiments of a photoelectric conversion device of the present invention will be described with reference to the drawings, which are not intended to limit the invention. It should be noted that the elements shown in the drawings are not to scale for ease of visual understanding.

Embodiments of the substrate for an electronic device of the invention are described. The substrate for an electronic device of the invention includes an insulating layer-provided metal substrate, on which an electrode layer, which may form an electronic device, such as a photoelectric conversion circuit, is disposed.

### Substrate for Electronic Device of First Embodiment

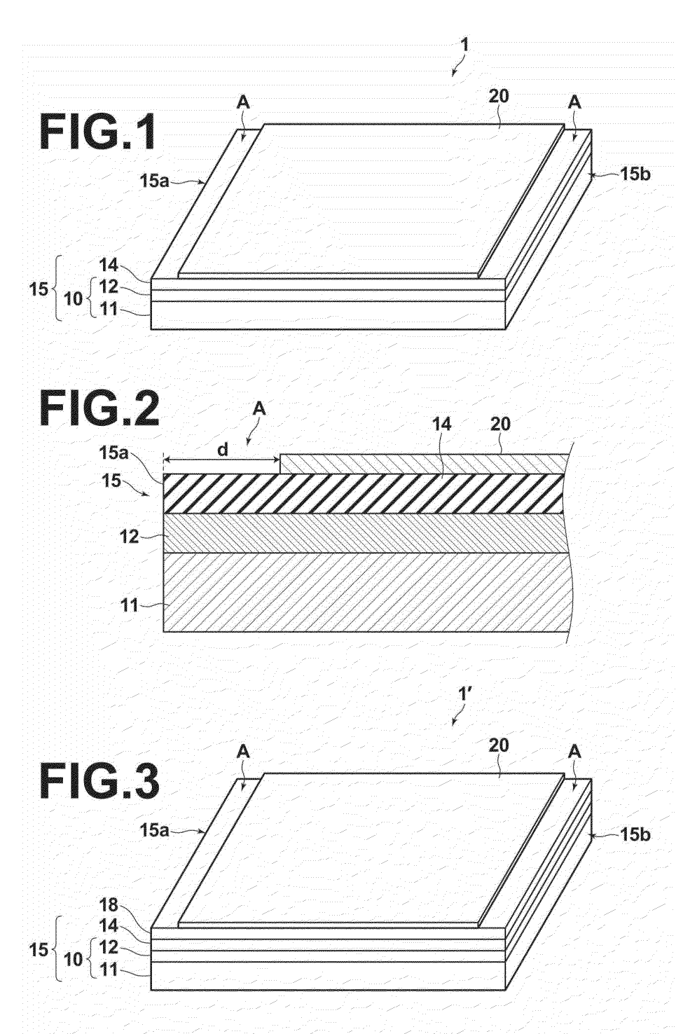

FIG. 1 is a perspective view schematically illustrating a substrate 1 for an electronic device of a first embodiment.

The substrate 1 for an electronic device of this embodiment includes an insulating layer-provided metal substrate 15 formed by a metal substrate 10 and an insulating layer 14 disposed on the surface of the metal substrate 10, and an electrode layer 20 disposed on the insulating layer 14.

The metal substrate 10 is formed by an Al material 12 and a base material 11 made of a metal different from the Al material, which are joined together. The metal substrate 10 includes the Al layer on at least one surface thereof. The metal substrate 10 is not limited to the metal substrate 10 of this embodiment, which is formed by the Al material and a metal different from the Al material joined together, and may be formed only by the Al material.

The metal substrate 10 may preferably be formed by pressure joining the base material 11 and the Al material 12. It may be particularly preferable that the pressure joining is achieved without heating. The joining without heating refers to that the joining is achieved at room temperature without externally applying heat.

It is desirable that the base material 11 is formed by a metal having a smaller coefficient of linear thermal expansion, higher rigidity and higher heat resistance than Al.

It is desirable that the material forming the base material 11 is a metal having a smaller coefficient of linear thermal expansion, higher rigidity and higher heat resistance than Al, and the material may be selected, as appropriate, according to a result of a stress calculation based on material properties of the insulating layer-provided metal substrate 15 and the electronic device to be formed thereon. In a case where the electronic device is a photoelectric conversion circuit that forms a compound semiconductor solar battery, a steel or Ti material is preferable. Preferable examples of the steel material may include, for example, austenitic stainless steel (coefficient of linear thermal expansion: 17×10⁻⁶/° C.), carbon steel (10.8×10⁻⁶/° C.), and ferritic stainless steel (10.5×10⁻⁶/° C.), 42 invar alloy or Kovar alloy (5×10⁻⁶/° C.), 36 invar alloy (<1×10⁻⁶/° C.), etc. As the Ti material, for example, Ti (9.2×10⁻⁶/° C.) may be used. However, the Ti material is not limited to pure Ti, and Ti-6Al-4V or Ti-15V-3Cr-3Al-3Sn, which are wrought alloys having almost the same coefficient of linear thermal expansion as that of Ti may preferably be used.

The thickness of the base material 11 may be any thickness that is set in view of ease of handling (strength and flexibility) during the production process and during operation; however, the thickness may preferably in the range from 10 μm to 1 mm.

The main component of the Al material 12 may be highly-pure Al or a 1000 series pure Al according to the Japanese Industrial Standards (JIS), or an alloy of Al and a different metal element, such as Al—Mn alloy, Al—Mg alloy, Al—Mn—Mg alloy, Al—Zr alloy, Al—Si alloy or Al—Mg—Si alloy (see “Aluminum Handbook”, the 4th edition (1990, published by the Japan Institute of Light Metals)). The highly-pure Al may contain a slight amount of various metal elements, such as Fe, Si, Mn, Cu, Mg, Cr, Zn, Bi, Ni and Ti, in the form of solid solution. The total amount of components other than Al, or impurities, in the Al alloy may preferably be less than 10 wt %, that is, the purity of Al may preferably be 90 wt % or more, in view of ensuring the insulating property of the anodized area after anodization. In particular, in order to more effectively reduce a leakage current when a high voltage of 200 V or more is applied, an Al purity of 99 wt % or more is more preferable.

The thickness of the Al material 12 may be selected as appropriate; however, it may preferably be in the range from 0.1 to 500 μm in the form of the Al material 12 of the insulating layer-provided metal substrate 15.

The insulating layer 14 is formed by an anodized film (anodized alumina film), which is formed by anodizing the surface of the Al material 12 of the metal substrate 10. In particular, the anodized film may preferably be a so-called porous alumina having a porous structure.

The anodization can be achieved by immersing the metal substrate 10, which serves as the anode, in an electrolytic solution together with a cathode, and applying a voltage between the anode and the cathode.

Before the anodization, the surface of the Al material 12 may be subjected to washing, polishing and smoothing, etc., as necessary. As the cathode, carbon, Al, or the like, may be used. The electrolyte is not particularly limited, and an acidic electrolytic solution that contains one or two or more acids, such as sulfuric acid, phosphoric acid, chromic acid, oxalic acid, sulfamic acid, benzenesulfonic acid and amidosulfonic acid, may preferably be used as the electrolyte. Anodization conditions are not particularly limited, and depend on the type of electrolyte used. Examples of appropriate conditions may include: an electrolyte concentration in the range from 1 to 80 mass %, a solution temperature in the range from 5 to 70° C., a current density in the range from 0.005 to 0.60 A/cm², a voltage in the range from 1 to 200 V and an electrolysis time in the range from 3 to 500 minutes. The electrolyte may preferably be sulfuric acid, phosphoric acid or oxalic acid, or a mixed solution thereof. When the above-described electrolyte is used, an electrolyte concentration in the range from 4 to 30 mass %, a solution temperature in the range from 10 to 30° C., a current density in the range from 0.002 to 0.30 A/cm² and a voltage in the range from 20 to 100 V are preferable.

During the anodization, the oxidation reaction progresses in a substantially perpendicular direction from the surface of the Al material 12 to form the anodized film 14 on the surface of the Al material 12. In a case where the above-described acidic electrolytic solution is used, the anodized film 14 formed is a porous anodized film, where a number of microcolumns, which are regular hexagonal when viewed from the top, are closely arranged, each microcolumn has, at the center thereof, a micropore having a round bottom surface, and a barrier layer (which usually has a thickness of 0.02 to 0.1 μm) is formed at the bottom of the microcolumns. Such a porous anodized film has a lower Young's modulus of the film than a non-porous aluminum oxide single-component film, and has higher bending resistance and higher resistance to cracks that form due to a difference of thermal expansion at high temperature. It should be noted that, in a case where the electrolysis is performed using a neutral electrolytic solution, such as boric acid, in place of the acidic electrolytic solution, a compact anodized film (non-porous aluminum oxide single-component film) forms in place of the porous anodized film formed by the arranged microcolumns. After the porous anodized film is formed using the acidic electrolytic solution, a pore filling process, where electrolysis is performed again using the neutral electrolytic solution, may be performed to increase the thickness of the barrier layer of the anodized film. The thicker barrier layer contributes to higher insulating property of the film.

It is desirable that the anodized film 14 is formed to have a uniform thickness in the range from 5 μm to 50 μm, or more preferably in the range from 9 μm to 20 μm.

The thickness of the anodized film 14 can be controlled by controlling the magnitudes of the current or voltage during constant current electrolysis or constant voltage electrolysis, and electrolysis time.

The electrode layer 20 is formed on the anodized film 14, which is the insulating layer of the insulating layer-provided metal substrate 15. Specifically, the electrode layer 20 is formed only on an area of the anodized film 14 other than the end areas A at opposite two sides of the anodized film 14.

FIG. 2 is a sectional view for explaining the relationship between the end area A of the substrate 15 and the position at which the electrode layer 20 is formed.

As shown in FIG. 2, the electrode layer 20 is not provided at the end area A, which is a range of a predetermined distance d from an end face 15a, and is formed only at an inner area of the substrate that is away from the end face by the distance d. The same applies to the distance of the position at which the electrode layer 20 is formed from an end face 15b.

The distance d is 200 μm or more, or more preferably is 300 μm or more.

It should be noted that the substrate 1 for a device of this embodiment is obtained by cutting a flexible long substrate in a direction perpendicular to the unwinding direction of the long substrate. Namely, the substrate 1 for a device of this embodiment is produced by anodizing a long metal substrate in a roll-to-roll process, forming the electrode layer by sputtering, or the like, in a roll-to-roll process, and then, cutting the long substrate in the direction perpendicular to the unwinding direction of the long substrate.

In the substrate 1 shown in FIG. 1, the opposite two sides including the end areas A are formed when the long substrate is cut in the direction perpendicular to the long sides of the substrate. That is, the end faces 15a, 15b are cut faces.

In the production process, the electrode layer is formed in a state where a mask is formed on the end areas A of the insulating layer 14, and then, the mask is removed to leave the electrode layer 20 only at the area other than the end areas A, thereby providing the electrode layer 20 at the area other than the end areas A.

Alternatively, the electrode layer may be formed uniformly on the insulating layer 14 without masking the end areas A, and parts of the electrode layer in the range of the distance d from the cutting positions may be removed. Then, the substrate may be cut at the cutting positions to provide the individual substrates with the electrode formed only at the area other than the end areas A. Still alternatively, after the long substrate is cut at desired positions, parts of the electrode layer formed at the end areas A in the range of the distance d from the cut end faces may be removed by laser scribing, or the like, to provide the individual substrates with the electrode formed only at the area other than the end areas A.

The present inventors have found that, by providing the electrode layer only at the inner area that is away from the cut end faces by a distance of 200 μm or more, the electrode layer is scarcely affected by the cracks that form in the anodized film 14 due to the cutting, and high insulation between the electrode layer 20 and the metal substrate 10 can be maintained (see “verification experiment”, which will be described later).

Further, the present inventors have found that, by providing the electrode layer only at the inner area that is away from the cut end faces by a distance of 300 μm or more, further reduction of the influence of the cracks is achieved.

Still further, the present inventors have found that, when the electronic device formed on the insulating layer-provided metal substrate is driven, a phenomenon where an electric current (surface leakage current) flows from the surface of the insulating layer to the metal substrate occurs under predetermined conditions. The present inventors also have found that, in order to prevent such a surface leakage current, it is preferable to form the electronic device at the inner area that is away from the cut faces by a distance of 300 μm or more.

As described above, the substrate for an electronic device of this embodiment has the electrode layer that is provided in an area where sufficient insulation is ensured, thereby increasing the reliability of the electronic device formed on the substrate.

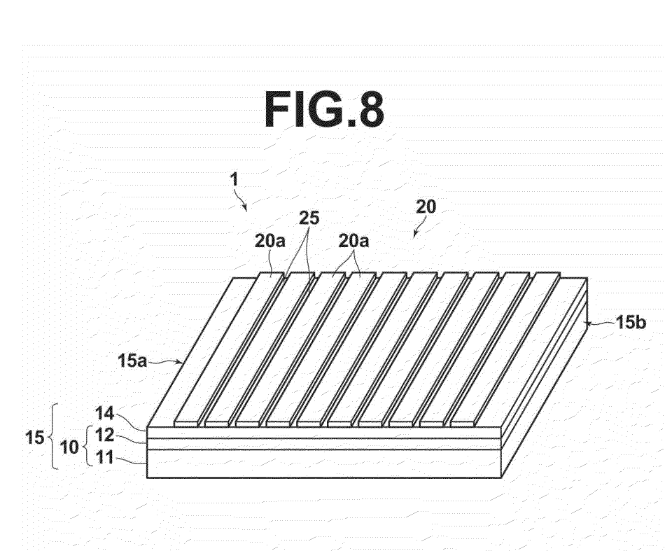

It should be noted that, although the electrode layer 20 is formed as a uniform layer in the above-described embodiment, the electrode layer 20 may be formed in any of various patterns depending on the electronic device formed on the substrate. For example, if an integrated solar battery is formed as the device, the electrode layer may be formed in a pattern where a uniform electrode layer is provided with scribe lines for separating a plurality of stripe electrodes from each other (see FIG. 8). Further, if the substrate for an electronic device is used as a circuit board, an electrode layer having a wiring pattern may be provided.

The material forming the electrode layer 20 is not particularly limited, as long as the material is usable as an electrode. The method for forming the electrode layer 20 is not particularly limited, and examples thereof may include gas-phase film formation processes, such as electron beam deposition and sputtering.

In a case where the substrate of the invention is used as a substrate for a solar battery, the material forming the electrode layer 20 may preferably be Mo, and the thickness of the electrode layer 20 may be 100 nm or more, or may preferably be in the range from 0.45 to 1.0 μm.

A modification of this embodiment is shown in FIG. 3. As shown in FIG. 3, a layer 18 made of SLG (soda-lime glass), for example, and having a thickness of about 50 to 200 nm may be provided between the insulating layer 14 and the electrode layer 20. The thickness of the insulating layer 18 is within a range where the flexibility of the substrate is not impaired.

In a case where a compound semiconductor photoelectric conversion element, in particular, a photoelectric conversion element including a CIGS photoelectric conversion layer, is formed as the electronic device, it is preferable to provide a substrate 1′ which includes the insulating layer 18 made of SLG as an alkali element source for the CIGS photoelectric conversion layer.

Even when the insulating layer having a thickness of about 200 nm is formed, large cracks form in the anodized film in the vicinity of the cut end faces, and therefore the same problem of short circuit, etc., between the electrode layer 20 and the metal substrate 10 occurs at the end areas A. By providing the electrode layer 20 only at the inner area that is away from the cut end faces 15a, 15b by a distance of 200 μm or more, or more preferably 300 μm or more, higher reliability during the formation of the electronic device is provided.

### Substrate for Electronic Device of Second Embodiment

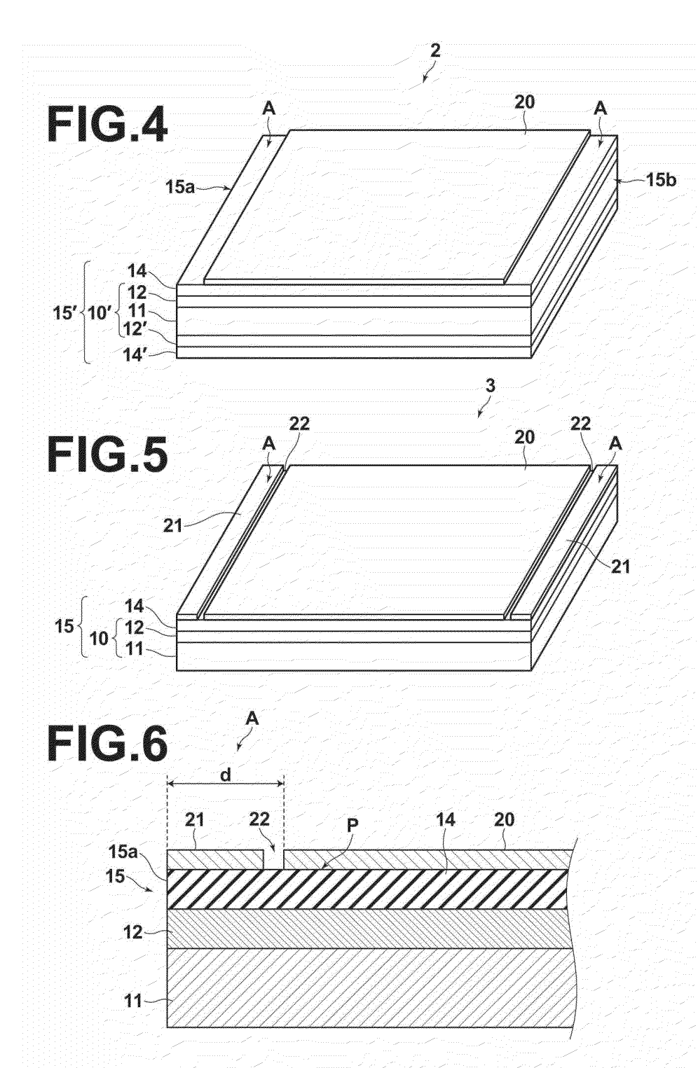

FIG. 4 is a perspective view schematically illustrating a substrate 2 for an electronic device of a second embodiment. The same elements as those of the substrate 1 for an electronic device of the first embodiment are designated by the same reference numerals and are not described in detail.

The substrate 2 for an electronic device of this embodiment includes an insulating layer-provided metal substrate 15′, which is formed by a metal substrate 10′ and insulating layers 14 and 14′ disposed at the front side and the back side of the metal substrate 10′, and the electrode layer 20 disposed on the insulating layer 14.

As shown in FIG. 4, the substrate 2 for an electronic device of this embodiment has a three layered structure where the metal substrate 10′ includes Al materials 12 and 12′ on the opposite surfaces of the base material 11, and the surfaces of the Al materials 12 and 12′ are anodized to form the anodized Al films 14 and 14′, which serve as the electric insulation layers, on the surfaces of the Al materials. That is, the insulating layer-provided metal substrate 15′ has a five layered structure including the anodized film 14, the Al material 12, the base material 11, the Al material 12′ and the anodized film 14′.

The electrode layer 20 is formed only on the anodized film 14. The insulating layer-provided metal substrate 15′ is rectangular, and the electrode layer 20 is provided only on an area of the insulating layer-provided metal substrate 15′ other than the end areas A at the opposite two sides of the insulating layer-provided metal substrate 15′.

The range of the area in which the electrode layer 20 is formed is the same as that in the first embodiment (see FIG. 2), and the same effect as that of the first embodiment is provided by the substrate 2 for an electronic device of this embodiment.

### Substrate for Electronic Device of Third Embodiment

FIG. 5 is a perspective view schematically illustrating a substrate 3 for an electronic device of a third embodiment. The same elements as those of the substrate 1 for an electronic device of the first embodiment are designated by the same reference numerals and are not described in detail.

The substrate 3 for an electronic device of this embodiment includes the same insulating layer-provided metal substrate 15 as that of the substrate 1 for an electronic device of the first embodiment shown in FIG. 1, except that electrode layers 21 are provided on the end areas A of the insulating layer-provided metal substrate 15.

The electrode layer 20 and the electrode layers 21 are electrically separated from each other by scribe lines 22. The electrode layer 20 and the electrode layers 21 may be formed by forming a continuous uniform layer on the insulating layer-provided metal substrate 15, and then, separating the layers by laser scribing to form the scribe lines 22.

In a production process using a roll-to-roll process, each scribe line 22 may be formed at a position at the distance d from each cutting position, and then, the substrate may be cut later at the cutting position, or the substrate may be cut first, and then, each scribe line 22 may be formed at a position at the distance d from each cut end face.

With reference to FIG. 6, an area where each scribe line 22 is formed is described. FIG. 6 is a sectional view illustrating the relationship between the end area A of the substrate 15 and the position at which the scribe line 22 is formed.

As shown in FIG. 6, the scribe line 22 is formed such that the electrode layer 20 is formed at a position away from the cut end face 15a by the distance d.

The distance d is 200 μm or more, or more preferably is 300 μm or more.

As described above, the electrode layers 20 and 21 are separated from each other by the scribe lines 22, and therefore the same effect as that of the first and second embodiments is provided by the substrate 3 for an electronic device of this embodiment.

As a modification of the substrate 3 for an electronic device of this embodiment, the insulating layer-provided metal substrate 15′, which includes the Al material 12 and the anodized film 14 on the opposite surfaces of the base material 11, may be provided, similarly to the substrate 2 for a device of the second embodiment. In a case where a photoelectric conversion circuit is formed as the electronic device, it is preferable to provide a SLG layer between the anodized film 14 and the electrode layer 20, similarly to one shown in FIG. 3.

Now, a photoelectric conversion device according to embodiments of the invention, which includes the above-described substrate for an electronic device, is described.

### Photoelectric Conversion Device of First Embodiment

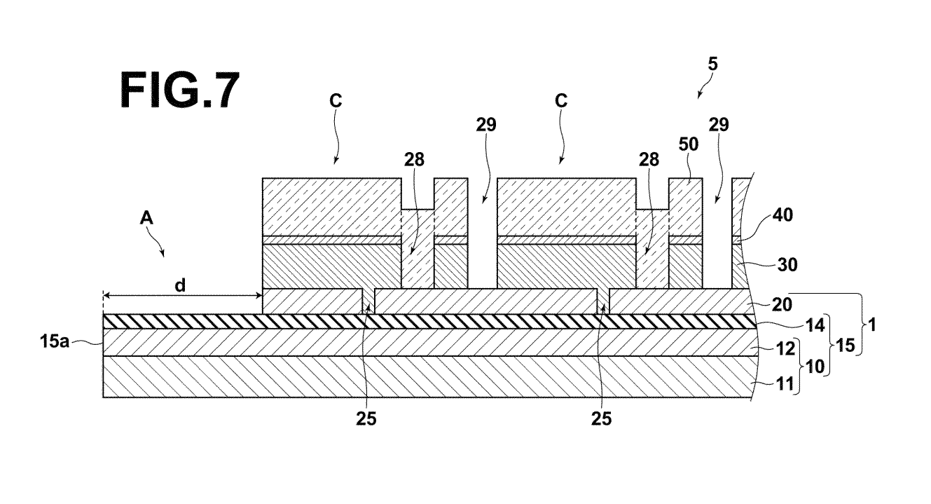

FIG. 7 is a sectional view illustrating a part of an integrated solar battery 5, which is a photoelectric conversion device of a first embodiment.

The solar battery 5 of this embodiment includes a photoelectric conversion layer 30 made of a compound semiconductor, and is an integrated solar battery, where a number of photoelectric conversion element structures are electrically connected in series to achieve high voltage output.

The solar battery 5 of this embodiment is formed by the photoelectric conversion layer 30 made of a compound semiconductor, a buffer layer 40 and a surface electrode (transparent electrode) 50, which are formed in this order on the electrode layer 20 of the substrate 1 for an electronic device shown in FIG. 1.

In this example, the electrode layer 20 of the substrate 1 for an electronic device is subjected to scribing to form scribe lines 25 that separate the electrode layer 20 into a plurality of areas 20a in a stripe pattern, as shown in FIG. 8. The electrode layer 20 (20a) serves as the back electrode of the photoelectric conversion element.

As shown in FIG. 7, the photoelectric conversion layer 30 is formed on the electrode layer 20 (20a) to fill the scribe lines 25, and the buffer layer 40 is formed on the photoelectric conversion layer 30. In the buffer layer 40 and the photoelectric conversion layer 30, second scribe lines 28, which reach the back electrode, are formed at positions different from the positions of the scribe lines 25 and in parallel with the scribe lines 25, and the transparent electrode layer 50 is formed to fill the second scribe lines 28. In the transparent electrode layer 50, third scribe lines 29, which pass through the transparent electrode layer 50, the buffer layer 40 and the photoelectric conversion layer 30 to reach the electrode layer 20, are formed at positions different from the positions of the scribe lines 25 and 28 and in parallel with the scribe lines 25 and 28.

In the solar battery 5 of this embodiment, each second scribe line 28 is filled with the transparent electrode layer 50 so that the surface electrode 50 of a certain element (cell) C is connected in series to the back electrode layer 20 of the adjacent element C, thereby providing a photoelectric conversion circuit in which a number of elements C are integrated.

Namely, as shown in FIG. 7, in the solar battery 5 of this embodiment, the electrode layer 20, the photoelectric conversion layer 30, the buffer layer 40 and the electrode layer 50 are not formed on the end area A at the distance d from the cut end face 15a, and these layers are formed only at the inner area of the substrate that is away from the cut end face by the distance d.

The distance d is 200 μm or more, or more preferably is 300 μm or more.

The solar battery 5 is produced by, after the long metal substrate is anodized and the electrode layer is formed, forming the individual layers on the long substrate in a roll-to-roll process, and then, cutting the long substrate to form the above-described substrate 1 for an electronic device.

More specifically, the photoelectric conversion layer 30 and the buffer layer 40 are formed on the electrode layer 20, and scribe line processing to form the scribe lines 28 is performed. Then, the transparent electrode layer 50 is formed, scribe line processing to form the scribe lines 29 is performed, and then, the long substrate is cut in the direction perpendicular to the unwinding direction of the long substrate.

In the above-described production process, the individual layers (from the electrode layer 20 to the transparent electrode layer 50) are formed and the scribing is performed in a state where a mask is formed on the end areas A of the insulating layer 14, and then, the mask is removed to leave the individual layers only at the area other than the end areas A.

Alternatively, without masking the end areas A, the layers may be formed uniformly on the insulating layer 14 and the scribing, etc., may be performed. Then, parts of the layers formed in the range of the distance d from the cutting positions may be removed during the final scribing, and then, the substrate may be cut at the cutting positions, so that the layers are provided only at the area other than the end areas A. Still alternatively, before the layers formed at the end areas A are removed, the substrate may be cut at desired positions, and then, parts of the layers formed at the end areas A in the range of the distance d from the cut end faces may be removed by laser scribing, or the like, so that the layers are provided only at the area other than the end areas A.

As described previously, by providing the photoelectric conversion circuit only at the inner area that is away from the cut end faces by a distance of 200 μm or more, the photoelectric conversion circuit is scarcely affected by the cracks that form in the anodized film 14 due to the cutting, and high insulation between the electrode layer 20 and the metal substrate 10 can be maintained, thereby providing a highly reliable solar battery.

Further, by providing the photoelectric conversion circuit only at the inner area that is away from the cut end faces by a distance of 300 μm or more, further reduction of the influence of the cracks is achieved, thereby providing higher reliability.

It should be noted that, although the photoelectric conversion device of the above-described embodiment includes the above-described substrate 1 for an electronic device of the first embodiment, the photoelectric conversion device may include the substrate 1′ including the SLG layer 18, which has been described as the modification of the first embodiment. In this case, alkali ions can be diffused in the photoelectric conversion layer, thereby providing an effect of increasing the photoelectric conversion efficiency, which is more preferable.

Alternatively, the photoelectric conversion device may include the above-described substrate for an electronic device of the second embodiment.

Now, the individual layers of the solar battery 5 are described in detail.

### Photoelectric Conversion Layer

The photoelectric conversion layer 30 generates an electric charge when it absorbs light, and is formed by a compound semiconductor. In a case where the photoelectric conversion layer 30 is formed on the insulating layer-provided metal substrate via a lower electrode, the film formation is performed under the condition where the substrate temperature is 500° C. or more. By performing the film formation at the film formation temperature of 500° C. or more, the photoelectric conversion layer having good light absorption property and photoelectric conversion property can be provided.

The main component of the photoelectric conversion layer 3 is not particularly limited; however, it may preferably be at least one compound semiconductor having a chalcopyrite structure. In this case, the compound semiconductor is preferably at least one compound semiconductor formed by a group Ib element, a group IIIb element and a group VIb element.

Specifically, in view of providing high light absorption rate and high photoelectric conversion efficiency, it is preferable that the group Ib element is at least one element selected from the group consisting of Cu and Ag, the group IIIb element is at least one element selected from the group consisting of Al, Ga and In, and the group VIb element is at least one element selected from the group consisting of S, Se and Te.

Specific examples of the compound semiconductor include:

### CuAlS₂, CuGaS₂, CuInS₂,

### CuAlSe₂, CuGaSe₂, CuInSe₂ (CIS)

### AgAlS₂, AgGaS₂, AgInS₂,

### AgAlSe₂, AgGaSe₂, AgInSe₂,

### AgAlTe₂, AgGaTe₂, AgInTe₂,

Cu(In₁₋ₓGaₓ)Se₂ (CIGS), Cu(In₁₋ₓAlₓ)Se₂, Cu(In₁₋ₓGaₓ)(S,Se)₂,

### Ag (In₁₋ₓGaₓ)Se₂, and Ag(In₁₋ₓGaₓ)(S,Se)₂.

It is particularly preferable that the photoelectric conversion layer 30 contains CuInSe₂ (CIS) and/or Cu(In,Ga)Se₂ (CIGS) which is obtained by adding Ga to CuInSe₂ (CIS) to provide a solid solution. The CIS and CIGS are semiconductors having a chalcopyrite crystal structure and high light absorptance, and are reported to have high photoelectric conversion efficiency. Further, they are less susceptible to deterioration of efficiency due to exposure to light and have excellent durability.

The CIGS layer may be formed using any method, such as a simultaneous multi-source deposition process or a selenation process.

The main component of the photoelectric conversion layer 30 may be CdTe, which is a II-VI group compound semiconductor. The photoelectric conversion layer made of CdTe can be formed by a close-spaced sublimation process on a metal or graphite electrode formed as a lower electrode on the Al anodized film. The close-spaced sublimation process is a process where a CdTe material is heated to around 600° C. in a vacuum, and the CdTe crystal is condensed on the substrate which is at a lower temperature than the temperature of the CdTe material.

The thickness of the photoelectric conversion layer 30 is not particularly limited; however, a thickness in the range from 1.0 to 3.0 μm may be preferable, and a thickness in the range from 1.5 to 2.5 μm may be particularly preferable.

### Buffer Layer

The buffer layer 40 is formed by a layer mainly composed of CdS, ZnS, Zn(S,O), or Zn(S,O,OH). The buffer layer 40 may be formed, for example, using a CBD (chemical bath deposition) process. The thickness of the buffer layer 40 is not particularly limited; however, a thickness in the range from 10 nm to 0.5 μm may be preferable, and a thickness in the range from 15 to 200 nm may be more preferable.

### Transparent Electrode

The material forming the transparent electrode layer 50 is not particularly limited; however, n-ZnO, such as ZnO:Al, or the like, may be preferable. The thickness of the transparent electrode layer 50 is not particularly limited; however, a thickness in the range from 50 nm to 2 μm may be preferable.

### Other Layers

The solar battery 5 may include any layer other than the above-described layers, as necessary.

In the case where the solar battery 5 is provided in the form of a module, a cover glass, a protective film, etc., may be attached, as necessary.

When the solar battery 5 in the form of a module is provided, in general, a surface protective film, a back sheet, etc., are laminated via an adhesive filling layer. At this time, it is preferable in view of preventing a surface leakage current that the adhesive filling layer is adhered to portions at the ends of the substrate of the solar battery 5 where the anodized film 14 is exposed. As the adhesive filling layer, EVA (ethylene vinyl acetate) is preferably used.

### Photoelectric Conversion Device of Second Embodiment

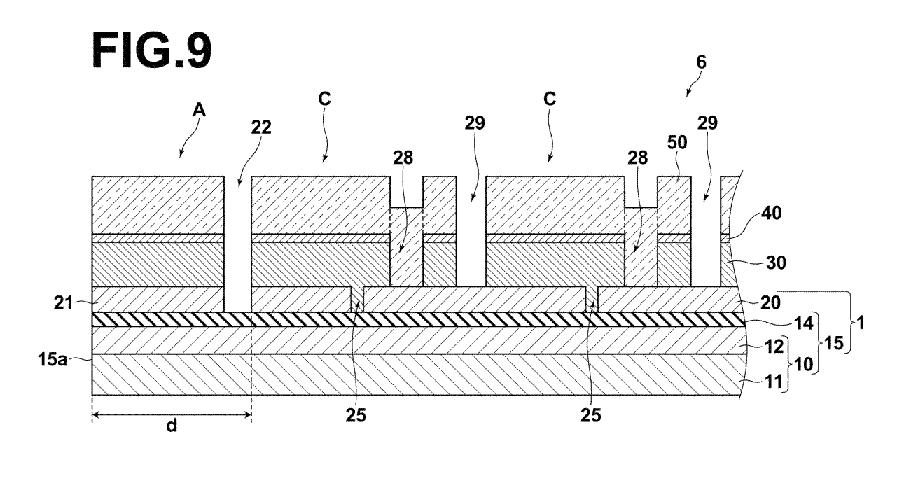

FIG. 9 is a sectional view illustrating a part of an integrated solar battery 6, which is a photoelectric conversion device of a second embodiment.

Similarly to the above-described solar battery 5, the solar battery 6 of this embodiment includes the photoelectric conversion layer 30 made of a compound semiconductor, and is an integrated solar battery, where a number of photoelectric conversion element structures are electrically connected in series to achieve high voltage output.

Similarly to the solar battery 5 of the first embodiment, the solar battery 6 includes the substrate 3 for an electronic device, which is subjected to the scribing to form the scribe lines 25 that separate the electrode layer 20 into the plurality of areas in the stripe pattern. The solar battery 6 differs from the solar battery 5 of the first embodiment in that the electrode layer 21, the photoelectric conversion layer 30, the buffer layer 40 and the transparent electrode layer 50 are also formed at the end areas A of the insulating layer-provided metal substrate 15.

The layers formed at each end area A are electrically separated from the elements C that are formed at the inner area relative to the scribe line 22. Only the elements formed at the inner area of the substrate relative to the scribe line 22 function as the elements (photoelectric conversion circuits) of the solar battery, and the layers formed at the end area A do not function as the elements of the solar battery 6.

As shown in FIG. 9, the scribe line 22 is formed such that the photoelectric conversion circuits are located at the inner area that is away from the cut end face 15a by the distance d.

The distance d is 200 μm or more, or more preferably is 300 μm or more.

Similarly to the solar battery 5 of the first embodiment, the solar battery 6 is produced by, after the long metal substrate is anodized and the electrode layer is formed, forming the individual layers on the long substrate in a roll-to-roll process, and then, cutting the long substrate to form the above-described substrate for an electronic device. More specifically, the photoelectric conversion layer 30 and the buffer layer 40 are formed on the electrode layer 20, and scribe line processing to form the scribe lines 28 is performed. Then, the transparent electrode layer 50 is formed, scribe line processing to form the scribe lines 29 is performed, and then, the long substrate is cut in the direction perpendicular to the unwinding direction of the long substrate.

In the above-described production process, the individual layers are uniformly formed on the insulating layer 14 and the scribing is performed. Then, the scribe lines 22 are formed at positions at the distance d from the cutting positions during the final scribing, and then, the substrate is cut at the cutting positions, thereby producing the solar battery shown in FIG. 9.

Alternatively, the substrate may be cut at predetermined positions before the scribe lines 22 are formed, and then, the scribe lines 22 may be formed at the positions at the distance d from the cut end faces during further scribing.

Also in this embodiment, by providing the photoelectric conversion circuit only at the inner area that is away from the cut end faces by a distance of 200 μm or more, the photoelectric conversion circuit is scarcely affected by the cracks that form in the anodized film 14 due to the cutting, and high insulation between the electrode layer 20 and the metal substrate 10 can be maintained, thereby providing a highly reliable solar battery.

Further, by providing the photoelectric conversion circuit only at the inner area that is away from the cut end faces by a distance of 300 μm or more, further reduction of the influence of the cracks is achieved, thereby providing higher reliability.

### Verification Experiment

Now, a verification experiment for the present invention is described.

### Method of Preparing Insulating Layer Provided Metal Substrate

An Al (30 μm)-SUS (100 μm)-Al (30 μm) cladding plate prepared by a cold rolling process was used as the metal substrate. The purity of Al was 99.5%, and anodization was performed.

Before the anodization, the metal substrate was washed with acetone and ethanol. As the electrolytic solution for the anodization, 0.5M aqueous oxalic acid solution was used. The temperature of the aqueous oxalic acid solution was controlled to be 16° C., and the substrate was immersed in the aqueous solution with using an Al plate as the counter electrode (cathode) and applying a voltage of 40 V to perform the anodization to provide an anodized film (aluminum oxide) having a thickness of 10 μm.

### Cutting

The substrate with the anodized film formed on the surface of the metal substrate through the above-described process was cut into pieces of 3 cm×3 cm. A press cutter was used for the cutting.

### Observation of Cut End Face

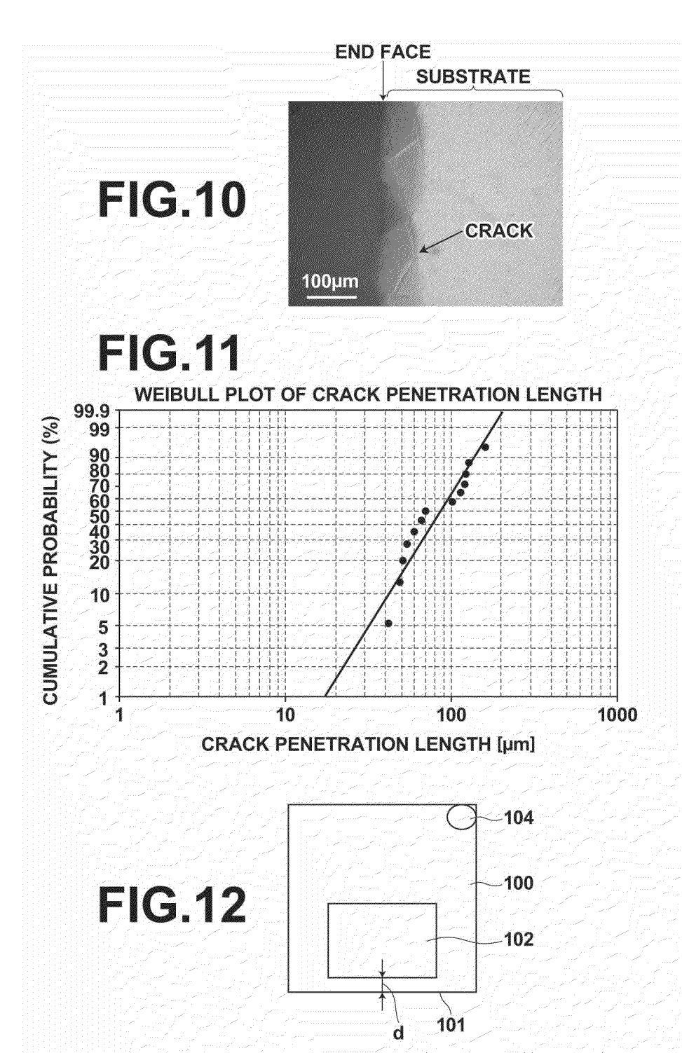

Cut end faces were observed and it was found that cracks formed in the anodized film around the cut positions. FIG. 10 is a microscopic image of the vicinity of a cut end face. As can be seen from FIG. 10, cracks formed from the end face of the substrate.

Using the cut pieces of 3 cm×3 cm of the substrate, the lengths of cracks penetrating from the cut end face were measured. Each sample was placed on a microstage, and the focus of the microscope was controlled on the end face of the substrate from above. Then, the maximum crack penetration length within the field of view of the microscope was measured on the microstage.

FIG. 11 shows a Weibull plot of the lengths of the cracks penetrating from the cut end faces of the pieces of substrate (13 samples) (crack penetration lengths), where the vertical axis represents cumulative probability (%) and the horizontal axis represents the crack penetration length (μm).

The measured values are distributed along the straight line shown in the drawing, and thus have the Weibull distribution.

As can be seen from the probability distribution plot shown in FIG. 11, cracks with the maximum penetration length of 160 μm from the cut end face were observed. As shown in FIG. 11, the crack penetration length has the Weibull distribution, and the probability of formation of a crack having a penetration length exceeding 160 μm is less than 10%. Therefore, in an area away from the cut end face by a length exceeding 160 μm, the influence of the cracks is very low. Further, it can be seen from FIG. 11 that the cumulative probability of formation of a crack having a penetration length of less than 200 μm exceeds 99%, and the probability of formation of a crack having a penetration length of 200 μm or more is less than 1%. Therefore, it is believed that an area away from the cut end face by a length of desirably 200 μm or more, or more desirably 300 μm or more, is scarcely affected by the cracks.

Although the crack penetration length may vary depending on the thickness of the anodized film, almost the same results were obtained at least within the range of the thickness of the anodized film from 5 μm to 18 μm.

Dependency of Breakdown on Distance from Cut End Face

For each of the 3 cm×3 cm pieces of insulating layer-provided metal substrate obtained as described above, an Mo electrode was formed on the insulating layer (anodized aluminum) and the withstand voltage was measured.

At this time, as shown in FIG. 12, an area within a distance d μm from a cut end face 101 of a substrate 100 was masked, and a Mo electrode 102 was formed only at the inner area that was away from the cut end face 101 by the distance d μm. The electrode had an area of 1 cm². The electrode 102 was formed at a position away from the other end of the substrate 100 by a sufficient distance (5 mm or more) so as not to be influenced by the other end. Further, a part of the anodized film on the surface of the substrate was removed to expose the metal layer portion (metal substrate) under the anodized film to form a tester connection area 104.

The insulating performance was verified by preparing a plurality of samples having different values of the distance d.

For each sample, resistance between the metal layer portion (tester connection area 104) under the anodized layer and the Mo electrode 102 was measured with a tester and evaluated such that a resistance of 1 MΩ or more is good and a resistance of less than 1 MΩ is bad.

Table 1 shows the result of evaluation.

TABLE 1

| d [μm] | Evaluation |
|---|---|
| 0 | Bad |
| 70 | Bad |
| 90 | Bad |
| 140 | Good |
| 160 | Bad |
| 200 | Good |
| 300 | Good |
| 395 | Good |
| 780 | Good |
| 1000 | Good |

As can be seen from Table 1, good results were obtained for all the samples having the distances d from the cut end face of 200 μm or more.

This result agrees with the result of the crack penetration lengths shown in FIG. 11. Therefore, it is clear that, in order to make the anodized film sufficiently work as the insulating layer, it is necessary to form an electrode layer or an electronic device in an area that is away from the cut end faces by a distance of 200 μm or more.

It has become clear from the above-described verification that, by providing an electrode layer only at the inner area of the substrate that is away from the cut end faces by a distance of 200 μm or more, or by providing an electrode layer where the inner area of the substrate that is away from the cut end faces by a distance of 200 μm or more and the end areas of the substrate are electrically separated by the scribe lines, as with the substrate for an electronic device of the invention, good insulation between the electrode layer on the inner area of the substrate and the metal substrate under the insulating layer is provided.

It is also clear that an electronic device formed on such a substrate has high reliability due to high voltage endurance between the metal substrate and the electrode layer.

What is claimed is:

1. A substrate for an electronic device, the substrate comprising:
an insulating layer-provided metal substrate comprising an anodized alumina film on the surface of a metal substrate, the insulating layer-provided metal substrate including a cut end face at at least one side thereof; and
an electrode layer provided on the insulating layer-provided metal substrate only at an inner area that is away from the cut end face by a distance of 200 μm or more.

2. The substrate for an electronic device as claimed in claim 1, wherein the electrode layer is provided only at an inner area that is away from the cut end face by a distance of 300 μm or more.

3. The substrate for an electronic device as claimed in claim 1, wherein the metal substrate is formed by an Al material and a metal base material that has a smaller coefficient of linear thermal expansion, higher rigidity and higher heat resistance than Al, which are integrated together.

4. The substrate for an electronic device as claimed in claim 3, wherein the metal base material is a steel material.

5. A substrate for an electronic device, the substrate comprising:
an insulating layer-provided metal substrate comprising an anodized alumina film on the surface of a metal substrate, the insulating layer-provided metal substrate including a cut end face at at least one side thereof; and
an electrode layer uniformly formed on the anodized alumina film on the insulating layer-provided metal substrate,
wherein the electrode layer is electrically separated into an end face area and an inner area at a predetermined position that is away from the cut end face of the insulating layer-provided metal substrate by a distance of 200 μm or more.

6. The substrate for an electronic device as claimed in claim 5, wherein the predetermined position is away from the cut end face by a distance of 300 μm or more.

7. The substrate for an electronic device as claimed in claim 5, wherein the metal substrate is formed by an Al material and a metal base material that has a smaller coefficient of linear thermal expansion, higher rigidity and higher heat resistance than Al, which are integrated together.

8. The substrate for an electronic device as claimed in claim 7, wherein the metal base material is a steel material.

9. A photoelectric conversion device comprising:
the substrate for an electronic device as claimed in claim 1; and
a photoelectric conversion layer and a transparent electrode layer formed in this order on the electrode layer of the substrate for an electronic device,
wherein the electrode layer, the photoelectric conversion layer and the transparent electrode layer form a photoelectric conversion circuit.

10. A photoelectric conversion device comprising:
the substrate for an electronic device as claimed in claim 5; and
a photoelectric conversion layer and a transparent electrode layer formed in this order on the electrode layer of the substrate for an electronic device,
wherein the photoelectric conversion layer and the transparent electrode layer, together with the electrode layer, are separated into an end face area and an inner area at the predetermined position, and the electrode layer, the photoelectric conversion layer and the transparent electrode layer formed at the inner area form a photoelectric conversion circuit.

11. The photoelectric conversion device as claimed in claim 9, wherein the photoelectric conversion layer is formed by a compound semiconductor, and
the photoelectric conversion device further comprises a buffer layer between the photoelectric conversion layer and the transparent electrode layer.

12. The photoelectric conversion device as claimed in claim 10, wherein the photoelectric conversion layer is formed by a compound semiconductor, and
the photoelectric conversion device further comprises a buffer layer between the photoelectric conversion layer and the transparent electrode layer.
